(19) United States
(12) Patent Application Publication
(10) Pub. No.: US 2013/0248764 A1
(43) Pub. Date: Sep. 26, 2013

(54) METHOD FOR INCREASING THE CONTENT OF CE3+ IN LASER MATERIALS

(71) Applicants: Ulrich Weichmann, Eindhoven (DE); Matthias Alexander Wilhelm Fechner, Eindhoven (DE); Fabian Reichert, Eindhoven (DE); Herbert Walter Klaus Petermann, Eindhoven (DE); Gunter Huber, Eindhoven (DE)

(72) Inventors: Ulrich Weichmann, Eindhoven (DE); Matthias Alexander Wilhelm Fechner, Eindhoven (DE); Fabian Reichert, Eindhoven (DE); Herbert Walter Klaus Petermann, Eindhoven (DE); Gunter Huber, Eindhoven (DE)

(73) Assignee: KONINKLIJKE PHILIPS ELECTRONICS N.V., EINDHOVEN (NL)

(21) Appl. No.: 13/989,566

(22) PCT Filed: Dec. 2, 2011
(86) PCT No.: PCT/IB2011/055429

§ 371 Date: May 24, 2013

(30) Foreign Application Priority Data
Dec. 6, 2010 (EP) 10193793.6

(51) Int. Cl. C30B 9/04; C30B 29/26; C09K 11/77

(52) U.S. Cl. CPC C30B 9/04; C09K 11/7718; C30B 29/26
USPC 252/301.4 R; 117/81

(57) ABSTRACT

The invention relates to a method of making Ce³⁺ containing laser materials with a fast cooling rate. This has been shown to dramatically increase the absorption rate of the 4f-5d-transition of Ce³⁺ within the laser material

### FIELD OF THE INVENTION

The present invention is directed to laser materials comprising Ce³⁺ and methods of their preparation.

### BACKGROUND OF THE INVENTION

Solid-state light sources are currently entering many different lighting applications and replace the traditional incandescent and gas discharge lamps. For applications with the highest optical demands (e.g. projection, optical fibre applications) lasers are considered the ideal light source. Many applications can already now be served with semiconductor diode lasers, however, when the application requires special wavelengths that are not or only inefficiently accessible with semiconductor diodes, usually diode pumped solid-state lasers are to be used to generate the desired laser wavelength.

Especially Cerium-containing materials, such as CaSc₂O₄:Ce and similar materials have gained the interest of the experts in the field due to their emittance in the visible wavelength area.

However, at present crystals grown by conventional growth techniques usually exhibit only an astonishingly low absorption at the excitation wavelength. Even charge compensation with co-doped ions and growth in reducing atmospheres does for most applications not lead to a drastic increase of the absorption coefficient.

### SUMMARY OF THE INVENTION

It is an object of the present invention to provide a method of manufacturing Cerium-containing laser materials with an emittance in the visible wavelength area in which the absorption rate, especially the absorption rate of the 4f-5d transition of Ce³⁺ is increased.

This object is solved by a laser material according to claim 1 of the present invention. Accordingly, a method for manufacturing Cerium-containing laser materials with an emittance in the visible wavelength area is provided comprising the steps
a) Heating the laser material and/or suitable precursors to a temperature of ≧1800° C.
b) Cooling to a temperature of ≦300° C. within ≦40 h (cooling time)

The term “laser material” in the sense of the present invention especially means and/or includes a material which is the active material in a solid-state laser and therefore shows absorption at the pump wavelength as well as stimulated emission at the laser wavelength. It should be noted that the term “laser materials” is used for all materials which essentially are laser materials (the same goes in analogy for all further materials mentioned in this application, especially the material Ca₁₋ₓ(Sc,Mg)₂O₄:Ceₓ which will later on be discussed).

“Essentially” in the sense of the present invention means and/or includes especially >90 (wt-)%, more preferred >95 (wt-)% and more preferred >98 (wt-)%.

The term “precursor materials” in the sense of the present invention especially means and/or includes material which will—at least partly—form the laser material after undergoing the steps a) and b) according to the invention. Suitable precursor materials in the sense of the present invention are especially oxides (although the invention is not limited to these materials) as will be shown later on.

Surprisingly it has been found that the use of such a method has for a wide range of applications within the present invention at least one of the following advantages:
The absorption rate of the optically active medium within the laser material can easily and effectfully be enhanced.
The method does not need sophisticated set-up and can be performed using standard apparatusses
With this method the fabrication of large crystals is possible, whereas other growth techniques with high temperature gradients during growth runs usually deliver only small pieces of crystals.

According to a preferred embodiment, in step a) the laser material and/or suitable precursors is heated to a temperature of ≧2000° C., more preferred ≧2150° C. This has been shown to speed up the manufacturing process as well as for some application to furthermore increase the absorption rate of the trivalent Ce.

According to a preferred embodiment, in step b) the cooling time is ≦20 h, more preferred ≦12 h and most preferred ≦9 h.

According to a preferred embodiment of the present invention, in step b) the cooling time is ≦−64/ln([Ce])h, whereby [Ce] is the molar dotation level of Ce.

It has been found for most applications within the present invention that in case the dotation level is higher, the cooling time can be allowed to be a little higher whereas with a low dotation level the cooling time should be shorter.

Preferably in step b) the cooling time is ≦−50/ln([Ce])h, more preferred the cooling time is ≦−40/ln([Ce])h.

According to a preferred embodiment of the present invention, the laser material is an orthorhombic material showing a 5d-4f transition. Such materials as such are known, e.g. from the EP application 10166783, which is hereby incorporated by reference. It has been found that the present invention is especially useful in the context of these materials although the invention is not limited to that.

According to a preferred embodiment of the present invention, the laser material is Ca₁₋ₓ(Sc,Mg)₂O₄:Ceₓ. It should be noted that Mg is usually present only in minor amounts (or not present at all).

According to a preferred embodiment of the present invention, the dotation level of Ce (=the numeral x in the above formula) is ≧0.001. It has been found out in practice that a lower dotation level will lead to laser materials which usually are not usable in actual applications or only with great difficulty.

According to a preferred embodiment of the present invention, the dotation level of Ce (=the numeral x in the above formula) is ≧0.0025 and ≦0.2. It has been found that if the dotation level is too high (i.e. over 0.2 or 20%), in many application the desired laser material will not form (or only to a very low extend), therefore it is for most applications useful to limit the upper end of the dotation to 0.2. Preferably the dotation level of Ce (=the numeral x in the above formula) is ≧0.004 and ≦0.01.

The present invention furthermore relates to a system comprising a laser material made according to the present invention and being used in one or more of the following applications:
Solid-state lasers
digital projection
fibre-optical applications
medical applications of solid-state lasers
heating applications
scintillation applications
x-ray detectors
γ-ray detectors
high-energy particle detectors
generation of ultrashort pulses
Fluorescence microscopy
Spectroscopy
Biophotonics
Photolithography

The aforementioned components, as well as the claimed components and the components to be used in accordance with the invention in the described embodiments, are not subject to any special exceptions with respect to their size, shape, material selection and technical concept such that the selection criteria known in the pertinent field can be applied without limitations.

### BRIEF DESCRIPTION OF THE DRAWINGS

Additional details, features, characteristics and advantages of the object of the invention are disclosed in the subclaims, the figures and the following description of the respective figures and examples, which—in an exemplary fashion—show several embodiments and examples of laser materials according to the invention.

FIG. 1 shows four absorption spectra of materials, three of them made according to the present invention and a fourth comparative material.

FIG. 2 shows an absorption spectrum of a further material made according to the present invention.

### EXPERIMENTAL SECTION

The invention is furthermore illustrated by the following examples and comparative examples which are merely to further explain the invention and which are not binding.

### GENERAL METHOD

All inventive and comparative examples were made according to the following method:

Suitable amounts of Sc₂O₃ and CeO₂ and CaO (purity 5N) were admixed in a Rhenium-crucible and heated up to 2300° C. in atmosphere consisting of 5% H₂, about 95% N₂ and 300 ppm O₂. The crucible was put in the center of a water-cooled induction coil; power was generated by a RF generator with a maximum power of 36 kW. The temperature was controlled by an optical pyrometer. After heating for about 90 min. the mixture was cooled down in such a fashion that within a preset amount of time (=cooling time) the temperature was lowered to ≦300° C. Usually, single crystals of high optical quality were obtained. The orthorhombic phase of CaSc₂O₄ was confirmed by X-Ray diffraction measurements.

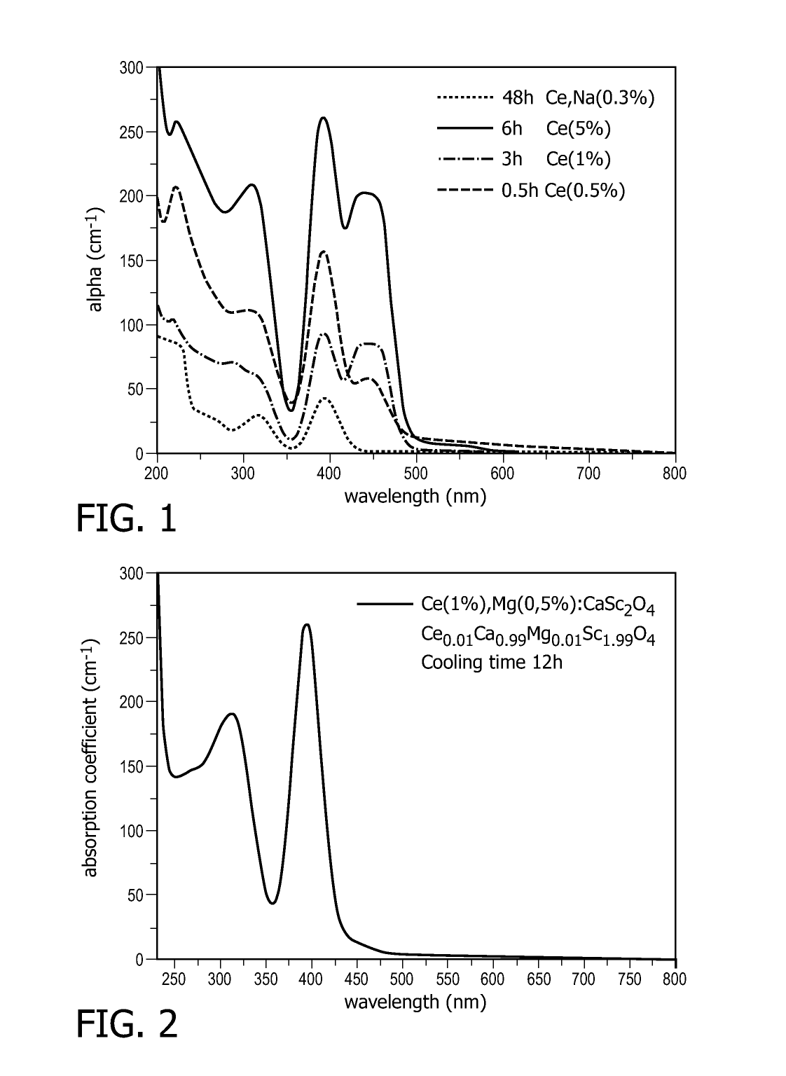

FIG. 1 shows four absorption spectra of materials, three of them made according to the present invention and a fourth comparative material. The data are shown in Table I:

TABLE I

| Example | Dotation level of Ce | Cooling time |
|---|---|---|
| Inventive Example I | 0.05 (=5%) | 6 h |
| Inventive Example II | 0.01 (=1%) | 3 h |
| Inventive Example III | 0.005 (=0.5%) | 0.5 h |
| Comparative Example | 0.003 (=0.3%) | 48 h |

It can clearly be seen that even with a very low dotation level by performing the inventive method a good absorption of the 4f-5d transition of Ce³⁺ can be achieved, whereas in the comparative example the absorption is lower.

A spectrum of a further material made according to the present invention can be seen in FIG. 2; the material is Ca_{0.99}Sc_{1.99}Mg_{0.01}O₄:Ce_{0.01}. Cooling time is 12 h. Also here a good absorption can be observed.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. The invention's scope is defined in the following claims and the equivalents thereto. Furthermore, reference signs used in the description and claims do not limit the scope of the invention as claimed.

1. A method of manufacturing Cerium-containing laser materials with an emittance in the visible wavelength area, comprising the steps of:
a) Heating the laser material and/or suitable precursors to a temperature of ≧1800° C.
b) Cooling to a temperature of ≦300° C. within ≦40 h (cooling time), wherein the laser material is Ca₁₋ₓ(Sc,Mg)₂O₄:Ceₓ or Ca₁₋ₓSc₂O₄:Ceₓ

2. The method of claim 1, whereby the cooling time is preferably ≦12 h, more preferably ≦9 h.

3. The method of claim 1, whereby in step a) the laser material and/or suitable precursors is heated to a temperature of ≧2000° C.

4. The method of claim 1, wherein the cooling time is ≦−64/ln([Ce])h, preferably ≦50/ln([Ce])h, more preferably ≦−40/ln([Ce])h, wherein [Ce] is the molar dotation level of Ce.

5. The method of claim 1, wherein the laser material is an orthorhombic material showing an 5d-4f transition.

6. (canceled)

7. The method of claim 1, wherein the dotation in the laser material is ≧0.001.

8. The method of claim 1, wherein the dotation in the laser material is ≧0.0025 and ≦0.2, preferably ≧0.004 and ≦0.1.

9. A system comprising a laser material made according to claim 1, the system being used in one or more of the following applications:
Solid-state lasers
digital projection
fibre-optical applications
medical applications of solid-state lasers
heating applications
scintillation applications
x-ray detectors
-ray detectors
high-energy particle detectors
generation of ultrashort pulses
Fluorescence microscopy
Spectroscopy
Biophotonics
Photolithography
